(19) United States
(12) Patent Application Publication
(10) Pub. No.: US 2024/0356435 A1
(43) Pub. Date: Oct. 24, 2024

(54) VOLTAGE BOOST CIRCUIT AND SENSOR DEVICE

(71) Applicant: Panasonic Intellectual Property Management Co., Ltd., Kadoma-shi, Osaka (JP)

(72) Inventor: Masaaki Nagai, Osaka (JP)

(73) Assignee: Panasonic Intellectual Property Management Co., Ltd., Kadoma-shi, Osaka (JP)

(21) Appl. No.: 18/685,304

(22) PCT Filed: Jul. 27, 2022
(86) PCT No.: PCT/JP2022/028983

§ 371 Date: Feb. 21, 2024

(30) Foreign Application Priority Data
Aug. 27, 2021 (JP) 2021-139308

(51) Int. Cl. H02M 3/07; G01P 15/125; G01R 15/04; G01R 19/00

(52) U.S. Cl. CPC H02M 3/07; G01P 15/125; G01R 15/04; G01R 19/0038

(57) ABSTRACT

A voltage boost circuit includes an input node, a voltage booster, a voltage divider, a comparator unit, and a voltage boost controller. The input node receives, from a reference signal source, a reference signal defined by a reference voltage. The voltage booster boosts an input voltage to deliver an output voltage. The voltage divider divides the output voltage into a fractional voltage to generate a fractional voltage signal defined by the fractional voltage. The comparator unit compares the reference signal and the fractional voltage signal with each other to generate a comparison signal. The voltage boost controller controls, in accordance with the comparison signal, operation of the voltage booster to narrow a difference between the reference voltage and the fractional voltage.

### TECHNICAL FIELD

The present disclosure generally relates to a voltage boost circuit and a sensor device, and more particularly relates to a voltage boost circuit including a voltage booster for boosting input voltage to deliver an output voltage and a sensor device including such a voltage boost circuit.

### BACKGROUND ART

Patent Document 1 discloses a voltage booster device. The voltage booster device of Patent Document 1 compares a fractional voltage of the output voltage of a charge pump circuit with a reference voltage and selectively drives, based on the result of the comparison, a plurality of voltage boosting stages set by the charge pump circuit, thereby performing feedback control on the voltage boosting capability of the charge pump circuit. Specifically, when a power supply is turned on, the charge pump circuit drives with a relatively high, second voltage boosting capability. Thus, as the supply voltage rises, a second fractional voltage, produced by dividing the output voltage, also rises accordingly. Then, when the second fractional voltage reaches the reference voltage while the supply voltage is rising (i.e., when the supply voltage rises to a certain degree), the charge pump circuit changes the voltage boosting capability into a relatively low, first voltage boosting capability to cut down power consumption. After that, the charge pump circuit is allowed to drive with the first voltage boosting capability to output a first boosted voltage in a period during which the supply voltage is stabilized.

Patent Document 2 discloses a voltage boost circuit. The voltage boost circuit of Patent Document 2 includes a voltage booster, a first voltage divider circuit, a constant current source, a second voltage divider circuit, a comparator unit, and a voltage boost controller. The voltage booster receives not only an input voltage from a power supply but also a voltage boosting clock signal and boosts an input voltage to a predetermined output voltage. The first voltage divider circuit divides, by a resistance ratio, the output voltage of the voltage booster to produce a fractional voltage. The constant current source is connected to a ground potential from the voltage output of the first voltage divider circuit. The second voltage divider circuit divides, by a resistance ratio, the input voltage from the power supply to generate a control voltage. The comparator unit compares the fractional voltage with the control voltage to output the result of the comparison. The voltage boost controller receives an output signal of the comparator unit and an operating clock signal and supplies the voltage boosting clock signal to the voltage booster.

### CITATION LIST

### Patent Literature

Patent Document 1: JP 2003-289663 A
Patent Document 2: JP 2005-73437 A

### SUMMARY OF INVENTION

An object of the present disclosure is to provide a voltage boost circuit with the ability to generate an output voltage with a desired waveform while contributing to downsizing and a sensor device including such a voltage boost circuit.

A voltage boost circuit according to an aspect of the present disclosure includes an input node, a voltage booster, a voltage divider, a comparator unit, and a voltage boost controller. The input node receives, from a reference signal source, a reference signal defined by a reference voltage. The voltage booster boosts an input voltage to deliver an output voltage. The voltage divider divides the output voltage into a fractional voltage to generate a fractional voltage signal defined by the fractional voltage. The comparator unit compares the reference signal and the fractional voltage signal with each other to generate a comparison signal. The voltage boost controller controls, in accordance with the comparison signal, operation of the voltage booster to narrow a difference between the reference voltage and the fractional voltage.

A sensor device according to another aspect of the present disclosure includes the voltage boost circuit described above and an inertial sensor. The output voltage is applied to the inertial sensor from the voltage booster of the voltage boost circuit.

### BRIEF DESCRIPTION OF DRAWINGS

FIG. 1 is a block diagram of a sensor device according to an exemplary embodiment;

FIG. 2 is a block diagram of a voltage boost circuit included in the sensor device;

FIG. 3 is a block diagram of a main part of the voltage boost circuit;

FIG. 4 illustrates how a voltage booster included in the voltage boost circuit operates;

FIG. 5 illustrates how the voltage booster operates;

FIG. 6 shows respective waveforms of a reference voltage, an output voltage, and a fractional voltage of the voltage boost circuit;

FIG. 7 shows the waveform of the output voltage of the voltage boost circuit;

FIG. 8 shows the waveform of the output voltage of the voltage boost circuit;

FIG. 9 is a block diagram of a capacitance controller included in the voltage boost circuit; and

FIG. 10 is a block diagram of a voltage boost circuit according to a comparative example.

### DESCRIPTION OF EMBODIMENTS

A voltage boost circuit according to an exemplary embodiment and a sensor device including the voltage boost circuit will now be described with reference to the accompanying drawings. Note that the exemplary embodiment to be described below is only an exemplary one of various embodiments of the present disclosure and should not be construed as limiting. Rather, the exemplary embodiment may be readily modified in various manners depending on a design choice or any other factor without departing from the scope of the present disclosure.

### (1) Overview

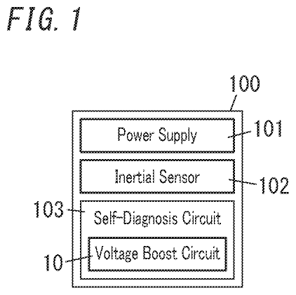

As shown in FIG. 1, a sensor device 100 according to an exemplary embodiment includes a voltage boost circuit 10 and an inertial sensor 102.

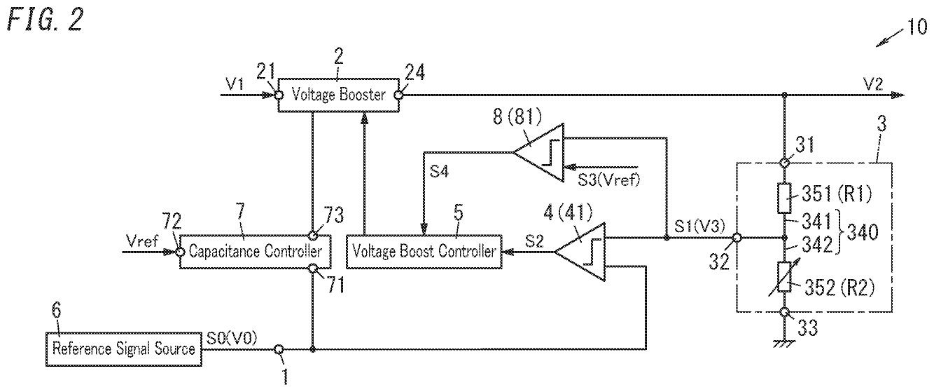

As shown in FIG. 2, the voltage boost circuit 10 includes an input node 1, a voltage booster 2, a voltage divider 3, a comparator unit 4, and a voltage boost controller 5.

The input node 1 receives, from a reference signal source 6, a reference signal S0 defined by a reference voltage V0. The voltage booster 2 boosts an input voltage V1 to deliver an output voltage V2. The voltage divider 3 divides the output voltage V2 into a fractional voltage V3 to generate a fractional voltage signal S1 defined by the fractional voltage V3. The comparator unit 4 compares the reference signal S0 and the fractional voltage signal S1 with each other to generate a comparison signal S2.

The voltage boost controller 5 controls, in accordance with the comparison signal S2, operation of the voltage booster 2 to narrow the difference between the reference voltage V0 and the fractional voltage V3. Specifically, the voltage boost controller 5 controls the operation of the voltage booster 2 to make the voltage booster 2 stop performing the voltage boosting operation when the fractional voltage V3 is greater than the reference voltage V0 and perform the voltage boosting operation when the fractional voltage V3 is equal to or less than the reference voltage V0.

In the voltage boost circuit 10 according to this embodiment and the sensor device 100 including the voltage boost circuit 10, the voltage boost controller 5 controls the operation of the voltage booster 2 to narrow the difference between the reference voltage V0 and the fractional voltage V3. In this case, the fractional voltage V3 is a voltage obtained by dividing the output voltage V2 of the voltage booster 2 (i.e., a voltage having the same waveform as the output voltage V2). Thus, making the voltage boost controller 5 control the operation of the voltage booster 2 allows the output voltage V2 of the voltage booster 2 to have the same waveform as the reference voltage V0. Consequently, the voltage boost circuit 10 according to this embodiment may shape the output voltage V2 of the voltage booster 2 into a desired waveform (i.e., the same waveform as that of the reference voltage V0) by setting a voltage with the desired waveform as the reference voltage V0. In addition, as will be described in detail later, the voltage boost circuit 10 according to this embodiment may also contribute to downsizing.

### (2) Details

The voltage boost circuit 10 and sensor device 100 according to this embodiment will now be described in further detail with reference to the accompanying drawings.

### (2.1) Sensor Device

As shown in FIG. 1, the sensor device 100 includes a power supply 101, the inertial sensor 102, and a self-diagnosis circuit 103.

The power supply 101 is a power supply for supplying driving power to the inertial sensor 102. The power supply 101 may include, for example, a constant voltage source that outputs a DC voltage. The power supply 101 outputs a constant DC voltage of about 3 V or about 5 V, for example.

The inertial sensor 102 is a so-called micro-electro-mechanical systems (MEMS) device.

The inertial sensor 102 transforms a physical quantity such as angular velocity, acceleration, angular acceleration, or velocity into an electrical signal. The inertial sensor 102 may be, for example, a 6-axis gyro sensor including a triaxial angular velocity sensor and a triaxial acceleration sensor. A sensor device 100 including this type of inertial sensor 102 may be used in various types of equipment including, for example, consumer electronic appliances, cellphones (including smartphones), cameras, wearable terminal devices, game consoles, and moving vehicles such as vehicles (including automobiles and motorcycles), drones, aircrafts, and watercrafts. In this embodiment, the sensor device 100 is supposed to be used as a piece of onboard equipment as an example.

The acceleration sensor of the inertial sensor 102 includes a substrate, a sensor mass, and a detector electrode. The sensor mass includes a sensor mass body and a moving electrode. The sensor mass body is held by the substrate to be movable with respect to the substrate using an elastic member, for example. The moving electrode is fixed to the sensor mass body. The detector electrode is fixed to the substrate. The detector electrode is disposed near the moving electrode to produce capacitance between the moving electrode of the sensor mass and itself. A sensor voltage, obtained by transforming the output voltage of the power supply 101, is applied between the moving electrode and the detector electrode. The potential difference between the moving electrode and the detector electrode is maintained at a predetermined value. In the acceleration sensor, when external acceleration (force) is applied to the acceleration sensor, inertial force is applied to the sensor mass according to the acceleration applied, thus causing the sensor mass to relatively move with respect to the substrate. This changes the distance between the moving electrode and the detector electrode, thus causing a variation in the capacitance between the moving electrode and the detector electrode. The acceleration sensor maintains the sensor voltage to maintain the potential difference between the moving electrode and the detector electrode at the predetermined value as described above. This allows the acceleration sensor to detect a variation in the capacitance according to the amount of current flowing into, or out of, the moving electrode and the detector electrode. The acceleration sensor outputs, as an acceleration signal, a signal representing the magnitude of the variation in the capacitance.

The acceleration sensor further includes a drive electrode. The drive electrode is fixed to the substrate. The drive electrode is disposed near the sensor mass. The drive electrode is an electrode for use to make self-diagnosis of the acceleration sensor. The drive electrode and the sensor mass are connected to the self-diagnosis circuit 103. When the acceleration sensor makes self-diagnosis, a drive voltage is applied from the self-diagnosis circuit 103 to between the drive electrode and the sensor mass to produce a potential difference between the drive electrode and the sensor mass. This drive voltage causes force that produces movement relative to the substrate (drive electrode), namely, electrostatic force, to be applied to the sensor mass. That is to say, this produces a state similar to a state where inertial force is applied to the sensor mass. The self-diagnosis of the acceleration sensor may be made by seeing, in this state, if the capacitance between the moving electrode and the detector electrode may be detected accurately.

As the drive voltage for driving the sensor mass, a voltage having a peak value of about 20 V and magnitude that varies in a sinusoidal wave may be used, for example. However, the power supply 101 just outputs a constant DC voltage of about 3 V or about 5 V as described above. That is why the self-diagnosis circuit 103 includes the voltage boost circuit 10 to generate the drive voltage based on the DC voltage supplied from the power supply 101.

### (2.2) Booster Circuit

Next, the voltage boost circuit 10 according to this embodiment will be described with reference to FIGS. 2-9.

FIG. 2 is a block diagram of the voltage boost circuit 10. As shown in FIG. 1, the voltage boost circuit 10 includes the input node 1, the voltage booster 2, the voltage divider 3, the comparator unit 4, the voltage boost controller 5, and the reference signal source 6.

The voltage booster 2 boosts the input voltage V1 to generate an output voltage V2 and delivers the output voltage V2 thus generated. The voltage booster 2 is a so-called “charge pump.”

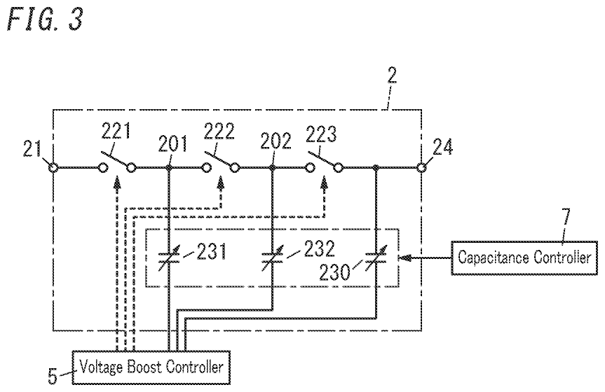

As shown in FIG. 3, the voltage booster 2 includes an input port 21, a first switch 221, a second switch 222, a third switch 223, a first capacitive element 231, a second capacitive element 232, an output-side capacitive element 230, and an output port 24.

The input port 21 is connected to the power supply 101. The input port 21 receives the input voltage V1 (a DC voltage with a constant voltage value) from the power supply 101.

A first terminal of the first switch 221 is connected to the input port 21. A second terminal of the first switch 221 is connected to a first terminal of the second switch 222. A second terminal of the second switch 222 is connected to a first terminal of the third switch 223. A second terminal of the third switch 223 is connected to the output port 24. As can be seen, the first switch 221, the second switch 222, and the third switch 223 are connected in series in this order between the input port 21 and the output port 24 such that the first switch 221 is located closer to the input port 21 than the second switch 222 or the third switch 223 is. The ON/OFF states of the first to third switches 221-223 are controlled by the voltage boost controller 5. In the following description, a connection node between the first switch 221 and the second switch 222 will be hereinafter referred to as a “first connection node 201” and a connection node between the second switch 222 and the third switch 223 will be hereinafter referred to as a “second connection node 202” for the sake of convenience of description.

The first capacitive element 231 has a first terminal connected to the first connection node 201 and has a second terminal connected to the voltage boost controller 5. The second capacitive element 232 has a first terminal connected to the second connection node 202 and has a second terminal connected to the voltage boost controller 5. The output-side capacitive element 230 has a first terminal connected to the output port 24 (more specifically, a connection node between the third switch 223 and the output port 24) and has a second terminal connected to the voltage boost controller 5. Each of the first capacitive element 231, the second capacitive element 232, and the output-side capacitive element 230 is a capacitor. The potential at the second terminal of the first capacitive element 231 and the potential at the second terminal of the second capacitive element 232 are controlled by the voltage boost controller 5. The potential at the second terminal of the output-side capacitive element 230 is maintained at a reference potential (i.e., the potential of the circuit ground, or 0 V).

The voltage boost controller 5 controls the operation of the voltage booster 2. The voltage boost controller 5 controls the ON/OFF states of the first to third switches 221-223, a potential at the second terminal of the first capacitive element 231, and a potential at the second terminal of the second capacitive element 232, thereby boosting the input voltage V1 applied to the voltage booster 2 to generate the output voltage V2.

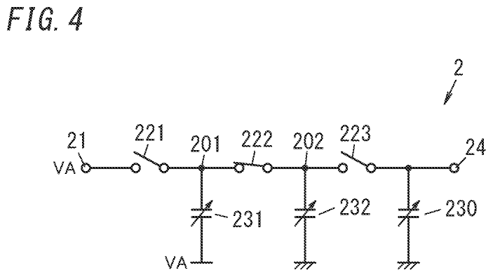

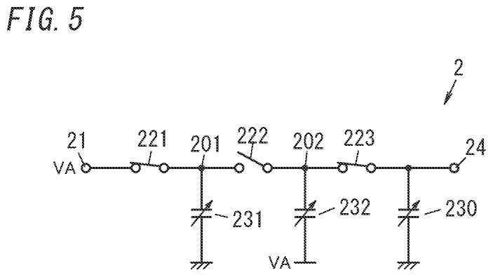

It will be described briefly with reference to FIGS. 4 and 5 how the voltage booster 2 performs a voltage boosting operation. In the following description, the voltage value of the input voltage V1 will be designated by “VA.”

First, the voltage boost controller 5 turns every switch (i.e., the first to third switches 221-223) ON and controls the potential at the second terminal of every capacitive element (i.e., the output-side capacitive element 230, the first capacitive element 231, and the second capacitive element 232) at the reference potential (of 0 V). As a result, a voltage corresponding to the voltage value VA is generated across each of the output-side capacitive element 230, the first capacitive element 231, and the second capacitive element 232. In addition, a quantity of electric charge corresponding to “C1×VA” is stored in the first capacitive element 231, a quantity of electric charge corresponding to “C2×VA” is stored in the second capacitive element 232, and a quantity of electric charge corresponding to “C0×VA” is stored in the output-side capacitive element 230, where “C1” is the capacitance value of the first capacitive element 231, “C2” is the capacitance value of the second capacitive element 232, and “C0” is the capacitance value of the output-side capacitive element 230.

Next, as shown in FIG. 4, the voltage boost controller 5 turns odd-numbered switches (namely, the first switch 221 and the third switch 223) OFF, turns the even-numbered switch (namely, the second switch 222) ON, sets the potential at the second terminal of the odd-numbered capacitive element (namely, the first capacitive element 231) at the voltage value VA of the input voltage V1, and sets the potential at the second terminal of the even-numbered capacitive element (namely, the second capacitive element 232) at the reference potential (of 0 V) (in a first step; refer to FIG. 4). Meanwhile, the voltage boost controller 5 maintains the potential at the second terminal of the output-side capacitive element 230 at the reference potential (of 0 V). This causes part of the electric charge stored in the first capacitive element 231 to flow into the second capacitive element 232 via the second switch 222, thus raising the potential at the second connection node 202 to a voltage value greater than the voltage value VA.

Subsequently, as shown in FIG. 5, the voltage boost controller 5 turns the odd-numbered switches (namely, the first switch 221 and the third switch 223) ON, turns the even-numbered switch (namely, the second switch 222) OFF, sets the potential at the second terminal of the odd-numbered capacitive element (namely, the first capacitive element 231) at the reference potential (of 0 V), and sets the potential at the second terminal of the even-numbered capacitive element (namely, the second capacitive element 232) at the voltage value VA of the input voltage V1 (in a second step; refer to FIG. 5). Meanwhile, the voltage boost controller 5 maintains the potential at the second terminal of the output-side capacitive element 230 at the reference potential (of 0 V). This causes part of the electric charge stored in the second capacitive element 232 to flow into the output-side capacitive element 230 via the third switch 223, thus raising the potential at the output port 24 to a voltage value greater than the voltage value VA. In addition, electric charge is also supplied from the input port 21 to the first capacitive element 231 via the first switch 221 to raise the potential at the first connection node 201 to VA.

The voltage boost controller 5 repeats the first and second steps to gradually increase the potential at the output port 24 (i.e., performs the voltage boosting operation). This allows the voltage boost controller 5 to gradually boost the output voltage V2 of the voltage booster 2.

In this case, the rate of increase in the potential at the output port 24 depends on the quantity of the electric charge transferred from the capacitive element on the preceding stage (i.e., on the input port 21 side) to the capacitive element on the following stage (i.e., on the output port 24 side) in one step (either the first step or the second step) of the voltage boosting operation. That is to say, the rate of increase in the potential at the output port 24 (i.e., the rate of increase in the output voltage V2 of the voltage booster 2) depends on the quantity of electric charge that can be stored in the capacitive element provided for the voltage booster 2 (in other words, depends on the capacitance of the capacitive element). The larger the capacitance of the capacitive element is, the larger the quantity of electric charge transferred from the capacitive element on the preceding stage to the capacitive element on the following stage in one step of the voltage boosting operation is (and therefore, the higher the rate of increase in the output voltage V2 is).

The maximum output voltage of the voltage booster 2 depends on the number of stages. As used herein, the “number of stages” refers to the number of series circuits, each including a switch and a capacitive element, which are included in the voltage booster 2 (i.e., the number of the series circuits connected in series between the input port 21 and the output port 24). The voltage booster 2 according to this embodiment includes three series circuits, each including a switch and a capacitive element. The potential at the output port 24 may increase at most to 3 VA (i.e., three times as high as VA). That is to say, the maximum value of the output voltage V2 of the voltage booster 2 according to this embodiment (hereinafter referred to as a “maximum output voltage”) is 3 VA.

Note that when the voltage booster 2 stops performing the voltage boosting operation with every switch of the voltage booster 2 turned OFF, the electric charge stored in the output-side capacitive element 230 will be released to an external device connected to the output port 24. Thus, the voltage at the output-side capacitive element 230 (i.e., the output voltage V2 of the voltage booster 2) decreases gradually.

As shown in FIG. 2, the voltage divider 3 includes a first port 31, a second port 32, and a third port 33.

The first port 31 is connected to the output port 24 of the voltage booster 2. The second port 32 is a port for outputting the fractional voltage signal S1 therethrough. The third port 33 is connected to a reference potential node. As used herein, the reference potential refers to a potential that sets a reference for the voltage boost circuit 10 and may be the circuit ground, for example. Typically, a circuit may be designed with the reference potential set at 0 V.

The first port 31 and the second port 32 are connected to each other via a first path 341. The second port 32 and the third port 33 are connected to each other via a second path 342. Each of the first path 341 and the second path 342 is a path through which electricity runs (i.e., a conductive path). A route 340 that connects the first port 31 and the third port 33 to each other includes the first path 341 that connects the first port 31 and the second port 32 to each other and the second path 342 that connects the second port 32 and the third port 33 to each other.

The first path 341 is provided with a first resistor 351. The second path 342 is provided with a second resistor 352.

The voltage divider 3 generates a fractional voltage V3 by dividing the output voltage V2 of the voltage booster 2 by a resistance ratio that is the ratio between the resistance value R1 of the first resistor 351 and the resistance value R2 of the second resistor 352. The voltage divider 3 outputs a fractional voltage signal S1 defined by the fractional voltage V3. That is to say, the fractional voltage signal S1 as an output signal of the voltage divider 3 is based on the resistance ratio that is the ratio between the resistance value R1 on the first path 341 and the resistance value R2 on the second path 342. In this embodiment, a voltage division ratio, which is defined as the ratio of the fractional voltage value of the fractional voltage V3 of the voltage divider 3 to the voltage value of the output voltage V2 of the voltage booster 2, is calculated by R2/(R1+R2).

In short, the fractional voltage V3, defining the fractional voltage signal S1 as an output signal of the voltage divider 3, has a voltage value having the same waveform (phase) as the output voltage V2 of the voltage booster 2 and obtained by decreasing the voltage value of the output voltage V2 based on the resistance ratio.

In this embodiment, the second resistor 352 has a variable resistance value R2. In other words, the voltage divider 3 includes a variable resistor (i.e., the second resistor 352) provided on the second path 342. This allows the resistance ratio of the voltage divider 3, and therefore, the voltage division ratio R2/(R1+R2), to be changed by changing the resistance value R2 of the second resistor 352. Changing the resistance ratio of the voltage divider 3 appropriately allows the amplitude of the fractional voltage V3 to be adjusted. Optionally, the resistance value R2 of the second resistor 352 may be changed by, for example, a user's external operation. Note that the “user” as used herein does not have to be a person who uses the voltage boost circuit 10 but may also be, for example, a device (machine) that sets the voltage boost circuit 10.

The reference signal source 6 generates a reference signal S0. The reference signal S0 has the reference voltage V0.

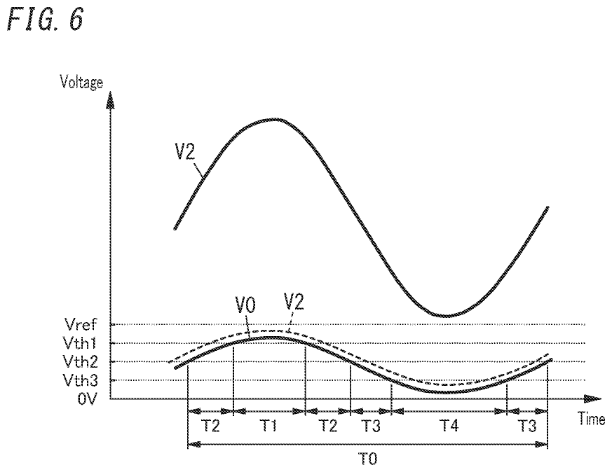

As will be described later, the voltage boost controller 5 controls the voltage booster 2 such that the waveform of the output voltage V2 of the voltage booster 2 is approximate to (i.e., corresponds to) the waveform of the reference voltage V0. Thus, the reference voltage V0 has a waveform that provides a reference waveform for the output voltage V2 to be generated by the voltage booster 2. For example, if the output voltage V2 of the voltage booster 2 (i.e., the output voltage V2 of the voltage boost circuit 10) is used as a drive voltage for the drive electrode as described above, then the reference signal S0 may be a signal having a waveform in which the reference voltage V0 varies periodically in a predetermined cycle T0 (more specifically, a sinusoidal wave signal in which the reference voltage V0 varies in a sinusoidal wave) as shown in FIG. 6. Note that the “sinusoidal wave signal” as used herein does not have to be a sinusoidal wave signal in a strict sense (i.e., a signal in which the voltage value changes continuously) but may also be a signal in which the voltage value changes stepwise to generally follow a sinusoidal wave as a reference.

The reference signal source 6 may, for example, receive a command value about a cycle (frequency) from an external device and generate a reference signal S0, of which the cycle is defined by the command value thus received. The reference signal source 6 may be implemented as an appropriate circuit.

The input node 1 receives the reference signal S0 from the reference signal source 6. The input node 1 may be, for example, a circuit pattern (conductor) or a terminal that connects the reference signal source 6 and the voltage booster 2 to each other.

As shown in FIG. 2, the comparator unit 4 includes a comparator 41. The comparator unit 4 compares the reference signal S0 generated by the reference signal source 6 with the fractional voltage signal S1 generated by the voltage divider 3 to generate a comparison signal S2. The comparator unit 4 outputs, as the comparison signal S2, a binary signal which comes to have, for example, a high level if the voltage value of the fractional voltage V3 is greater than the voltage value of the reference voltage V0 and which comes to have, for example, a low level if the voltage value of the fractional voltage V3 is equal to or less than the voltage value of the reference voltage V0.

The voltage boost controller 5 controls the operation of the voltage booster 2 in accordance with the comparison signal S2 supplied from the comparator unit 4. Specifically, the voltage boost controller 5 controls, in accordance with the comparison signal S2, the respective ON/OFF states of the first, second, and third switches 221, 222, 223, the potential at the second terminal of the first capacitive element 231, and the potential at the second terminal of the second capacitive element 232.

The voltage boost controller 5 controls the operation of the voltage booster 2 in accordance with the comparison signal S2 to narrow the difference between the reference voltage V0 and the fractional voltage V3. If the comparison signal S2 has a low level, the voltage boost controller 5 makes the voltage booster 2 perform the voltage boosting operation (i.e., perform the first and second steps repeatedly). That is to say, if the voltage value of the fractional voltage V3 is equal to or less than the voltage value of the reference voltage V0, then the voltage boost controller 5 performs the voltage boosting operation to increase the voltage value of the output voltage V2 output from the voltage booster 2. On the other hand, if the comparison signal S2 has a high level, then the voltage boost controller 5 makes the voltage booster 2 stop performing the voltage boosting operation. That is to say, if the voltage value of the fractional voltage V3 is greater than the voltage value of the reference voltage V0, then the voltage boost controller 5 stops performing the voltage boosting operation to decrease the voltage value of the output voltage V2 output from the voltage booster 2.

As can be seen, making the voltage boost controller 5 control the operation of the voltage booster 2 in accordance with the comparison signal S2 to narrow the difference between the reference voltage V0 and the fractional voltage V3 causes the fractional voltage V3 and the output voltage V2 to vary following the variation pattern of the reference voltage V0. Thus, the waveform of the output voltage V2 becomes approximate to (i.e., corresponds to) the waveform of the reference voltage V0. For example, if the reference voltage V0 has a voltage waveform that varies in a sinusoidal wave, then the output voltage V2 of the voltage booster 2 also has a voltage waveform that varies in a sinusoidal wave as shown in FIG. 6. Thus, the voltage boost circuit 10 according to this embodiment may generate an output voltage V2 having a desired waveform (i.e., a waveform corresponding to that of the reference voltage V0).

In addition, the voltage boost circuit 10 according to this embodiment may also regulate the gain (i.e., the ratio of the output voltage V2 to the input voltage V1) by adjusting the resistance ratio of the voltage divider 3. This enable, even if the deterioration with time of the voltage booster 2 has caused a decrease in the output voltage V2, for example, regulating (i.e., increasing) the output voltage V2 to a desired voltage value by adjusting the resistance ratio. In addition, since the magnitude of the output voltage V2 is variable, the same voltage boost circuit 10 may be used, for example, for a plurality of inertial sensors 102 which are required to have mutually different voltages.

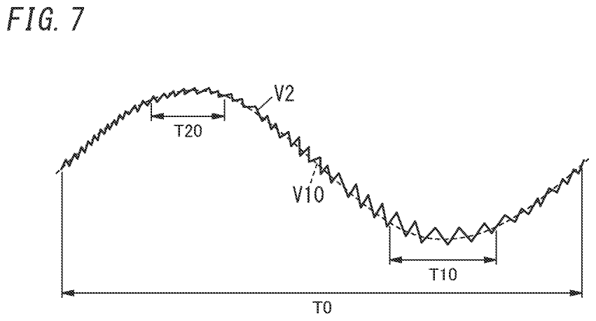

As described above, the voltage booster 2 increases and decreases the amplitude of the output voltage V2 by performing and stopping performing the voltage boosting operation as described above. Thus, the waveform of the output voltage V2 does not exactly match the waveform of a virtual voltage V10 (which is a sinusoidal waveform), which is supposed from the waveform of the reference voltage V0 but repeatedly increases and decreases finely during one cycle T0 as shown in FIG. 7. Note that FIG. 7 conceptually shows, in comparison, the waveform of the virtual voltage V10 used as a reference for the output voltage V2 and the waveform of an actual output voltage V2. In the waveform of the output voltage V2, a period in which the voltage value increases corresponds to a period in which the voltage boosting operation is performed, and a period in which the voltage value decreases corresponds to a period in which the voltage boosting operation stops being performed.

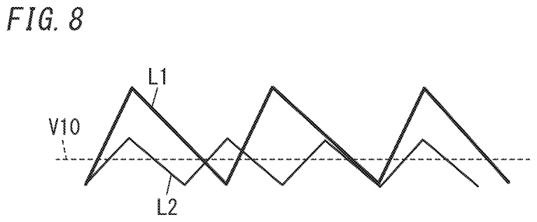

In this case, look closely at the waveform of the output voltage V2 for one cycle T0, and it can be seen that the waveform of the output voltage V2 is more significantly different from the waveform of the virtual voltage V10 in a period T10 in which the output voltage V2 has a relatively small voltage value than in a period T20 in which the output voltage V2 has a relatively large voltage value. This is because in the period T10 in which the output voltage V2 has a relatively small voltage value, the quantity of electric charge stored in advance in the output-side capacitive element 230 is smaller, and therefore, the quantity of electric charge supplied to the output-side capacitive element 230 in one step of the voltage boosting operation (i.e., either the first step or the second step) is larger, and the voltage increases at a higher rate, than in the period T20 in which the output voltage V2 has a relatively large voltage value. This feature is illustrated conceptually in FIG. 8. In FIG. 8, the bold polygon graph L1 indicates the deviation of the output voltage V2 from the virtual voltage V10 as a reference in the period T10 in which the output voltage V2 has a relatively small voltage value. Meanwhile, in FIG. 8, the fine polygon graph L2 indicates the deviation of the output voltage V2 from the virtual voltage V10 as a reference in the period T20 in which the output voltage V2 has a relatively large voltage value.

As can be seen, in the period T10 in which the output voltage V2 has a relatively small voltage value, the output voltage V2 may deviate more significantly from the virtual voltage V10. The deviation of the output voltage V2 from the virtual voltage V10 may be noise superposed on the output voltage V2.

Thus, to reduce the deviation (noise), the voltage boost circuit 10 according to this embodiment uses variable capacitance capacitive elements as the capacitive elements of the voltage booster 2 and causes the capacitances of the capacitive elements to vary within one cycle T0. This point will be described in further detail below.

In the voltage boost circuit 10 according to this embodiment, at least one of the first and second capacitive elements 231, 232 included in the voltage booster 2 is a variable capacitance capacitive element. More specifically, each of the first capacitive element 231 and the second capacitive element 232 is a variable capacitance capacitive element as shown in FIG. 3. In addition, in the voltage boost circuit 10 according to this embodiment, the output-side capacitive element 230 included in the voltage booster 2 is also a variable capacitance capacitive element as shown in FIG. 3.

Furthermore, the voltage boost circuit 10 further includes a capacitance controller 7 as shown in FIGS. 2 and 3. The capacitance controller 7 controls the capacitance of at least one variable capacitance capacitive element. In this embodiment, the capacitance controller 7 controls the capacitance of the first capacitive element 231, the capacitance of the second capacitive element 232, and the capacitance of the output-side capacitive element 230. More specifically, in this embodiment, the capacitance controller 7 controls, in response to the reference signal S0 supplied from the reference signal source 6, the respective capacitances of the variable capacitance capacitive elements (namely, the first capacitive element 231, the second capacitive element 232, and the output-side capacitive element 230).

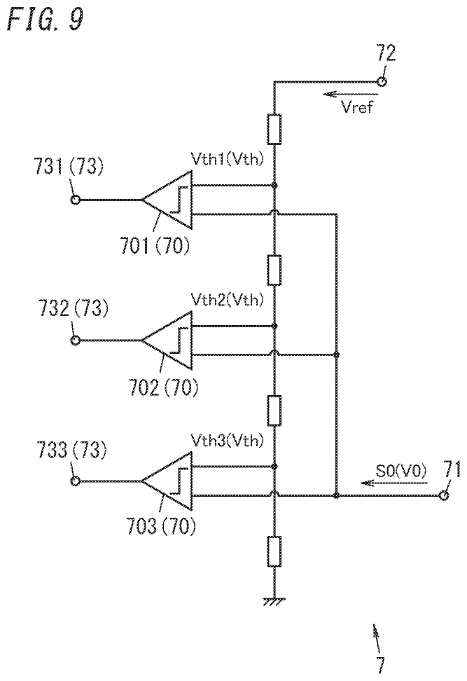

As shown in FIG. 9, the capacitance controller 7 includes comparators 70. In addition, the capacitance controller 7 also includes a first input port 71, a second input port 72, and output ports 73. The first input port 71 receives the reference signal S0. The second input port 72 receives a referential voltage Vref with a constant voltage value. The capacitance controller 7 divides the referential voltage Vref by the voltage dividing resistors to generate a threshold voltage Vth. Each comparator 70 compares the reference voltage V0 with the threshold voltage Vth. Then, the capacitance controller 7 varies the capacitance of the capacitive element as the reference voltage V0 changes with respect to the threshold voltage Vth.

The capacitance controller 7 controls the capacitance of the capacitive element such that the capacitance becomes smaller in a period in which the reference voltage V0 is equal to or less than the threshold voltage Vth (hereinafter referred to as a “second divided period”) than in a period in which the reference voltage V0 is greater than the threshold voltage Vth (hereinafter referred to as a “first divided period”). For example, the capacitance controller 7 may set the capacitance of the capacitive element at a first capacitance value in the first divided period and set the capacitance of the capacitive element at a second capacitance value (<the first capacitance value) in the second divided period.

As described above, when the voltage booster 2 performs the voltage boosting operation, the larger the capacitance of the capacitive element included in the voltage booster 2 is, the higher the rate of increase in the output voltage V2 of the voltage booster 2 becomes. Thus, the deviation (noise) in the second divided period may be reduced by controlling the capacitance of the capacitive element such that the capacitance decreases in the second divided period.

In summary, the capacitance controller 7 controls the respective capacitances of the variable capacitance capacitive elements (namely, the first capacitive element 231, the second capacitive element 232, and the output-side capacitive element 230) to make the capacitances smaller in the second divided period than in the first divided period. The first divided period is a period included in the cycle T0. The second divided period is a period which is also included in the cycle T0 and in which the reference voltage V0 is smaller than in the first divided period. The capacitance controller 7 compares the reference voltage V0 with the threshold voltage Vth to determine, when finding the reference voltage V0 greater than the threshold voltage Vth as a result of comparison, that the current period be the first divided period. The capacitance controller 7 also compares the reference voltage V0 with the threshold voltage Vth to determine, when finding the reference voltage V0 equal to or less than the threshold voltage Vth as the result of comparison, that the current period be the second divided period.

More specifically, the capacitance controller 7 according to this embodiment includes, as the comparators 70, three comparators 70 (namely, a first comparator 701, a second comparator 702, and a third comparator 703) as shown in FIG. 9. The first comparator 701 compares the reference voltage V0 with a first threshold voltage Vth1. The first threshold voltage Vth1 may be, for example, a voltage produced by multiplying the referential voltage Vref by 0.75. The second comparator 702 compares the reference voltage V0 with a second threshold voltage Vth2. The second threshold voltage Vth2 may be, for example, a voltage produced by multiplying the referential voltage Vref by 0.5. The third comparator 703 compares the reference voltage V0 with a third threshold voltage Vth3. The third threshold voltage Vth3 may be, for example, a voltage produced by multiplying the referential voltage Vref by 0.25. The first threshold voltage Vth1 is greater than the second threshold voltage Vth2 (i.e., Vth1>Vth2). The second threshold voltage Vth2 is greater than the third threshold voltage Vth3 (i.e., Vth2>Vth3).

The capacitance controller 7 divides, based on the results of comparisons between the reference voltage V0 and the first to third threshold voltages Vth1-Vth3, one cycle T0 into four divided periods (namely, a first divided period T1, a second divided period T2, a third divided period T3, and a fourth divided period T4). Specifically, the capacitance controller 7 compares the reference voltage V0 with the first threshold voltage Vth1 to determine, when finding the reference voltage V0 greater than the first threshold voltage Vth1 as a result of comparison, that the current period be the first divided period T1 (refer to FIG. 6). Also, the capacitance controller 7 compares the reference voltage V0 with each of the first threshold voltage Vth1 and the second threshold voltage Vth2 to determine, when finding the reference voltage V0 greater than the second threshold voltage Vth2 and equal to or less than the first threshold voltage Vth1 as a result of comparison, that the current period be the second divided period T2 (refer to FIG. 6). Furthermore, the capacitance controller 7 compares the reference voltage V0 with each of the second threshold voltage Vth2 and the third threshold voltage Vth3 to determine, when finding the reference voltage V0 greater than the third threshold voltage Vth3 and equal to or less than the second threshold voltage Vth2 as a result of the comparison, that the current period be the third divided period T3 (refer to FIG. 6). Furthermore, the capacitance controller 7 compares the reference voltage V0 with the third threshold voltage Vth3 to determine, when finding the reference voltage V0 equal to or less than the third threshold voltage Vth3 as a result of the comparison, that the current period be the fourth divided period T4 (refer to FIG. 6). Although it depends on how to set the starting point of one cycle T0, one cycle T1 may include one first divided period T1, two second divided periods T2, two third divided periods T3, and one fourth divided period T4.

The capacitance controller 7 controls the capacitance of each capacitive element to make the capacitance smaller in the second divided period T2 (i.e., a period in which the reference voltage V0 is greater than the second threshold voltage Vth2 and equal to or less than the first threshold voltage Vth1) than in the first divided period T1 (i.e., a period in which the reference voltage V0 is greater than the first threshold voltage Vth1). In addition, the capacitance controller 7 also controls the capacitance of each capacitive element to make the capacitance smaller in the third divided period T3 (i.e., a period in which the reference voltage V0 is greater than the third threshold voltage Vth3 and equal to or less than the second threshold voltage Vth2) than in the second divided period T2. Furthermore, the capacitance controller 7 also controls the capacitance of each capacitive element to make the capacitance smaller in the fourth divided period T4 (i.e., a period in which the reference voltage V0 is equal to or less than the third threshold voltage Vth3) than in the third divided period T3. For example, the capacitance controller 7 may set the capacitance of the capacitive element at a first capacitance value in the first divided period, set the capacitance of the capacitive element at a second capacitance value in the second divided period, set the capacitance of the capacitive element at a third capacitance value in the third divided period, and set the capacitance of the capacitive element at a fourth capacitance value in the fourth divided period, where “fourth capacitance value<third capacitance value<second capacitance value<first capacitance value” is satisfied.

Setting the capacitance of each of the capacitive elements included in the voltage booster 2 such that the smaller the reference voltage V0 in a given period is, the smaller the capacitance of the capacitive element is as described above enables reducing the deviation of the waveform of the output voltage V2 from that of the virtual voltage V10 in a period in which the output voltage V2 has a relatively small voltage value, thus eventually reducing the noise of the output voltage V2. For example, the first to fourth capacitance values may be set at such values that make the deviations (noise) of the output voltage V2 from the virtual voltage V10 approximately equal to each other in the first to fourth divided periods T1-T4, for example.

Note that the number of the threshold voltages Vth to be compared with the reference voltage V0 does not have to be three but may also be any other arbitrary number equal to or greater than one. For example, the capacitance controller 7 may include first to (N−1)^{th} comparators. The first to (N−1)^{th} comparators compare the reference voltage V0 with first to (N−1)^{th} threshold voltages, respectively. In this case, an (L+1)^{th} threshold voltage is less than an L^{th} threshold voltage, where L is an arbitrary integer falling within the range from 1 through N−2. The capacitance controller 7 may, based on a result of comparison of the reference voltage V0 with the first through (N−1)^{th} threshold voltages, determine as follows. That is, when finding the reference voltage V0 greater than the first threshold voltage as a result of comparisons, the capacitance controller 7 determines that the current period be the first divided period. When finding the reference voltage V0 greater than an (X+1)^{th} threshold voltage and equal to or less than an X^{th} threshold voltage as the result of comparisons, the capacitance controller 7 determines that the current period be an (X+1)^{th} divided period, where X is an arbitrary integer falling within the range from 1 through N−2. When finding the reference voltage V0 equal to or less than the (N−1)^{th} threshold voltage as the result of comparisons, the capacitance controller 7 determines that the current period be an N^{th} divided period. In addition, the capacitance controller 7 may control the capacitance of each capacitive element to make the capacitance smaller in an (M+1)^{th} divided period than in an M^{th} divided period, where M is an arbitrary integer falling within the range from 1 through N−1. In this case, the reference voltage V0 in the (M+1)^{th} divided period is less than the reference voltage V0 in the M^{th} divided period.

A specific configuration for the variable capacitance capacitive element is not limited to any particular one. For example, the variable capacitance capacitive element may include a plurality of series circuits, each including a capacitor and a switch, which are connected in parallel to each other, and may be configured to vary the capacitance by changing the number of capacitors to be connected via the switches. Alternatively, the variable capacitance capacitive element may also be, for example, a so-called “vari-cap,” of which the capacitance varies according to the bias voltage.

As shown in FIG. 2, the voltage boost circuit 10 further includes a failure diagnosis circuit 8. The failure diagnosis circuit 8 determines, based on a result of comparison between the fractional voltage signal S1 and a diagnosis signal S3, whether any failure has occurred in the voltage boost circuit 10. The diagnosis signal S3 may be, for example, a voltage signal having a constant voltage value. As shown in FIG. 2, the failure diagnosis circuit 8 includes a comparator 81. The failure diagnosis circuit 8 generates a decision signal S4 by comparing the fractional voltage signal S1 with the diagnosis signal S3. In this embodiment, the diagnosis signal S3 is defined by the referential voltage Vref. The failure diagnosis circuit 8 outputs, as the decision signal S4, a binary signal, which comes to have a high level if the voltage value of the fractional voltage V3 is greater than the voltage value of the voltage (referential voltage Vref) of the diagnosis signal S3 and which comes to have a low level if the voltage value of the fractional voltage V3 is equal to or less than the voltage value of the voltage of the diagnosis signal S3. If the decision signal S4 has the high level, it means that some failure has occurred to the voltage boost circuit 10. The failure diagnosis circuit 8 outputs the decision signal S4 to the voltage boost controller 5.

When finding that the decision signal S4 supplied from the failure diagnosis circuit 8 has the high level, for example, the voltage boost controller 5 determines that the voltage value of the output voltage V2 proportional to the voltage value of the fractional voltage V3 have increased abnormally and instructs the voltage booster 2 to stop performing the voltage boosting operation. This reduces the chances of the voltage boost circuit 10 delivering an output voltage V2, of which the amplitude is larger than an expected one.

### (3) Advantages

Next, the advantages of the voltage boost circuit 10 according to this embodiment will be described in comparison with a voltage boost circuit 10R according to a comparative example.

The voltage boost circuit 10R according to the comparative example, as well as the voltage boost circuit 10 according to the exemplary embodiment, is also a circuit for generating an output voltage having a desired waveform (i.e., a waveform corresponding to the waveform of the reference voltage V0).

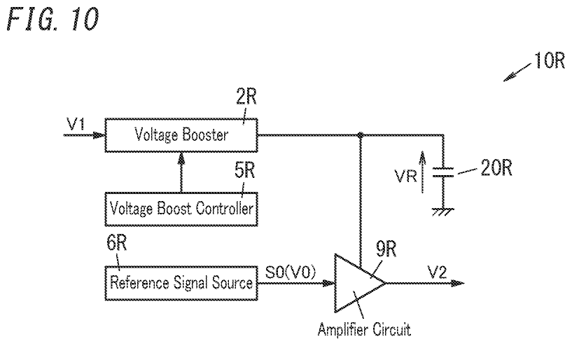

As shown in FIG. 10, the voltage boost circuit 10R according to the comparative example includes a voltage booster 2R, a voltage boost controller 5R, and a reference signal source 6R. In addition, the voltage boost circuit 10R according to this comparative example further includes an output stabilizing capacitive element 20R and an amplifier circuit 9R.

The voltage booster 2R according to this comparative example, as well as the voltage booster 2 according to the exemplary embodiment, is also implemented as a so-called “charge pump.” The voltage booster 2R generates an output voltage by boosting the input voltage V1. Unlike the voltage boost controller 5 according to the exemplary embodiment, the voltage boost controller 5R according to this comparative example makes the voltage booster 2R always perform the voltage boosting operation without receiving any comparison signal S2. Thus, unlike the voltage booster 2 according to the exemplary embodiment, the voltage booster 2R according to this comparative example generates a DC voltage VR having a constant voltage value (corresponding to the “maximum output voltage” described above).

The output stabilizing capacitive element 20R is an element corresponding to the output-side capacitive element 230 of the voltage booster 2 according to the exemplary embodiment. The voltage boost circuit 10R according to this comparative example includes the output stabilizing capacitive element 20R to maintain the output voltage (DC voltage VR) supplied from the voltage booster 2R at the maximum output voltage.

The reference signal source 6R according to this comparative example has the same configuration as the reference signal source 6 according to the exemplary embodiment, and also generates, just like the reference signal source 6, the reference signal S0 having a sinusoidal wave in which the reference voltage V0 varies periodically in the predetermined cycle T0.

The amplifier circuit 9R is a known amplifier circuit which uses an operational amplifier, for example. The amplifier circuit 9R generates an output voltage V2 by amplifying the reference voltage V0 using, as a driving power source, the DC voltage VR that has been generated by the voltage booster 2R (i.e., the output stabilizing capacitive element 20R).

As can be seen, the voltage boost circuit 10R according to this comparative example may generate an output voltage V2 having a desired waveform (i.e., a waveform corresponding to that of the reference voltage V0).

In the voltage boost circuit 10R according to this comparative example, however, the amplifier circuit 9R needs to be made up of elements (high-breakdown-voltage devices) that may operate at a voltage with a high voltage value (the DC voltage VR). This causes a significant increase in not only the circuit size of the amplifier circuit 9R but also the current consumed by the amplifier circuit 9R as well. In addition, in the voltage boost circuit 10R according to this comparative example, the voltage booster 2R is required to high current supply ability to supply a sufficient amount of current to the amplifier circuit 9R with a significantly large consumption current. This causes a significant increase in the circuit size of the voltage booster 2R. Furthermore, in the voltage boost circuit 10R according to this comparative example, the capacitance of the output stabilizing capacitive element 20R needs to be increased to supply a sufficient amount of current to the amplifier circuit 9R with a significantly large consumption current. This causes a significant increase in the circuit size of the output stabilizing capacitive element 20R. As can be seen, the voltage boost circuit 10R according to this comparative example includes elements that require relatively large circuit areas, and therefore, is difficult to have a reduced size.

In contrast, the voltage boost circuit 10 according to the exemplary embodiment includes no amplifier circuit 9R but generates an output voltage V2, having a waveform corresponding to the waveform of the reference voltage V0, by making the voltage booster 2 selectively perform (i.e., start and stop performing) the voltage boosting operation in accordance with the comparison signal S2. This eliminates the need to provide the amplifier circuit 9R, thus enabling reducing the circuit area by the area that would otherwise be left for the amplifier circuit 9R. In addition, eliminating the need to provide the amplifier circuit 9R with a significantly large current consumption also allows the voltage booster 2 to have significantly lower current supply ability, thus enabling reducing the circuit area of the voltage booster 2. Furthermore, eliminating the need to provide the amplifier circuit 9R with a significantly large current consumption also allows a capacitive element that needs a significantly large circuit area such as the output stabilizing capacitive element 20R to be omitted. In summary, in the voltage boost circuit 10 according to the exemplary embodiment, the voltage applied to elements other than the voltage booster 2 is a voltage that has not been boosted yet (i.e., about 3 V to about 5 V). This allows those elements other than the voltage booster 2 to be implemented as elements with a relatively low breakdown voltage, thus enabling reducing the circuit area.

In addition, in the voltage boost circuit 10 according to the exemplary embodiment, the voltage booster 2 includes the variable capacitance capacitive element as described above. Thus, adjusting the capacitance of the variable capacitance capacitive element enables reducing the noise caused to the output voltage V2 due to the voltage boosting operation.

Furthermore, the voltage boost circuit 10 according to the exemplary embodiment may also regulate the gain (i.e., the ratio of the output voltage V2 to the input voltage V1) by adjusting the resistance ratio of the voltage divider 3 as described above.

Besides, the voltage boost circuit 10 according to the exemplary embodiment may also generate an output voltage V2 with a desired waveform by appropriately adjusting the waveform of the reference signal S0 in terms of its cycle, for example.

### (4) Variations

Note that the embodiment described above is only an exemplary one of various embodiments of the present disclosure and should not be construed as limiting. Rather, the exemplary embodiment may be readily modified in various manners depending on a design choice or any other factor without departing from the scope of the present disclosure.

In one variation, the sensor device 100 does not have to be a piece of onboard equipment.

In another variation, the voltage boost circuit 10 may be used in a device other than the sensor device 100.

In still another variation, the reference signal S0 may also be a DC signal in which the voltage value of the reference voltage V0 does not vary. In that case, the output voltage V2 supplied from the voltage boost circuit 10 may be a DC voltage, of which the voltage value does not vary.

In yet another variation, the voltage booster 2 may also be a voltage booster device or circuit other than a charge pump. For example, the voltage booster 2 may also be a DC-DC converter.

In yet another variation, the number of stages of the voltage booster 2 does not have to be three but may also be two or four or more.

In yet another variation, the first resistor 351 may be a variable resistor. In that case, both the first resistor 351 and the second resistor 352 may be variable resistors. Alternatively, only the first resistor 351 may be a variable resistor.

In yet another variation, the comparator 70 of the capacitance controller 7 may compare either the output voltage V2 or the fractional voltage V3, not the reference voltage V0, with the threshold voltage Vth. Nevertheless, the output voltage V2 (and the fractional voltage V3) may vary when the resistance ratio of the voltage divider 3 is changed as described above. That is why it is preferable that the reference voltage V0 be compared with the threshold voltage Vth as in the exemplary embodiment described above.

In yet another variation, only some of the capacitive elements included in the voltage booster 2 may be variable capacitance capacitive elements. For example, only the capacitive element located closest to the input port 21 (i.e., the first capacitive element 231) and the capacitive element located closest to the output port 24 (i.e., the output-side capacitive element 230) may be variable capacitance capacitive elements, while the other capacitive element (the second capacitive element 232) may be a capacitive element with a fixed capacitance value. Alternatively, every capacitive element included in the voltage booster 2 may be a capacitive element with a fixed capacitance value.

### (5) Aspects

The exemplary embodiment and its variations described above are specific implementations of the following aspects of the present disclosure.

A voltage boost circuit (10) according to a first aspect includes an input node (1), a voltage booster (2), a voltage divider (3), a comparator unit (4), and a voltage boost controller (5). The input node (1) receives, from a reference signal source (6), a reference signal (S0) defined by a reference voltage (V0). The voltage booster (2) boosts an input voltage (V1) to deliver an output voltage (V2). The voltage divider (3) divides the output voltage (V2) into a fractional voltage (V3) to generate a fractional voltage signal (S1) defined by the fractional voltage (V3). The comparator unit (4) compares the reference signal (S0) and the fractional voltage signal (S1) with each other to generate a comparison signal (S2). The voltage boost controller (5) controls, in accordance with the comparison signal (S2), operation of the voltage booster (2) to narrow a difference between the reference voltage (V0) and the fractional voltage (V3).

This aspect enables generating an output voltage (V2) with a desired waveform while contributing to downsizing.

In a voltage boost circuit (10) according to a second aspect, which may be implemented in conjunction with the first aspect, the voltage booster (2) includes an input port (21), an output port (24), a first switch (221), a second switch (222), a third switch (223), a first capacitive element (231), and a second capacitive element (232). The input port (21) receives the input voltage (V1). The output port (24) delivers the output voltage (V2). The first switch (221), the second switch (222), and the third switch (223) are connected in series in this order between the input port (21) and the output port (24) such that the first switch (221) is located closer to the input port (21) than the second switch (222) or the third switch (223) is. The first capacitive element (231) has a first terminal connected to a connection node (first connection node 201) between the first switch (221) and the second switch (222) and has a second terminal connected to the voltage boost controller (5). The second capacitive element (232) has a first terminal connected to a connection node (second connection node 202) between the second switch (222) and the third switch (223) and has a second terminal connected to the voltage boost controller (5). The voltage boost controller (5) controls, in accordance with the comparison signal (S2), ON/OFF states of the first switch (221), the second switch (222), and the third switch (223), a potential at the second terminal of the first capacitive element (231), and a potential at the second terminal of the second capacitive element (232).

According to this aspect, implementing the voltage booster (2) as a so-called “charge pump” may contribute to reducing the size of the voltage boost circuit (10) compared to, for example, implementing the voltage booster (2) as a DC-DC converter.

In a voltage boost circuit (10) according to a third aspect, which may be implemented in conjunction with the second aspect, at least one of the first capacitive element (231) or the second capacitive element (232) is a variable capacitance capacitive element.

This aspect may reduce the noise caused to the output voltage (V2) due to the voltage boosting operation by the voltage booster (2).

In a voltage boost circuit (10) according to a fourth aspect, which may be implemented in conjunction with the third aspect, each of the first capacitive element (231) and the second capacitive element (232) is a variable capacitance capacitive element.

This aspect may reduce the noise caused to the output voltage (V2) due to the voltage boosting operation by the voltage booster (2).

A voltage boost circuit (10) according to a fifth aspect, which may be implemented in conjunction with the third or fourth aspect, further includes a capacitance controller (7) that controls capacitance of the variable capacitance capacitive element. The capacitance controller (7) controls the capacitance in response to the reference signal (S0).

According to this aspect, the variation in the voltage used as a reference is more stabilized than, for example, a situation where the capacitance is controlled based on the output voltage (V2), thus allowing the output voltage (V2) to be stabilized.

In a voltage boost circuit (10) according to a sixth aspect, which may be implemented in conjunction with the fifth aspect, the reference signal (S0) is a signal having a waveform in which the reference voltage (V0) varies periodically in a predetermined cycle (T0). The predetermined cycle (T0) includes: a first divided period; and a second divided period in which the reference voltage (V0) is smaller than in the first divided period. The capacitance controller (7) controls the capacitance to make the capacitance smaller in the second divided period than in the first divided period.

This aspect may reduce the noise caused to the output voltage (V2) due to the voltage boosting operation by the voltage booster (2).

In a voltage boost circuit (10) according to a seventh aspect, which may be implemented in conjunction with the sixth aspect, the capacitance controller (7) includes a comparator (70) that compares the reference voltage (V0) with a predetermined threshold voltage (Vth). The capacitance controller (7) compares the reference voltage (V0) with the predetermined threshold voltage (Vth) to determine, when finding the reference voltage (V0) greater than the predetermined threshold voltage (Vth) as a result of comparison, that a current period be the first divided period and determine, when finding the reference voltage (V0) equal to or less than the predetermined threshold voltage (Vth) as the result of the comparison, that the current period be the second divided period.

This aspect may reduce the noise caused to the output voltage (V2) due to the voltage boosting operation by the voltage booster (2).

In a voltage boost circuit (10) according to an eighth aspect, which may be implemented in conjunction with the fifth aspect, the reference signal (S0) is a signal having a waveform in which the reference voltage (V0) varies periodically in a predetermined cycle (T0). The predetermined cycle (T0) includes first through N^{th} divided periods, where N is an integer equal to or greater than 2. The reference voltage (V0) in an (M+1)^{th} divided period is less than the reference voltage (V0) in an M^{th} divided period, where M is an arbitrary integer falling within a range from 1 through N−1. The capacitance controller (7) controls the capacitance to make the capacitance smaller in the (M+1)^{th} divided period than in the M^{th} divided period.

This aspect may reduce the noise caused to the output voltage (V2) due to the voltage boosting operation by the voltage booster (2).

In a voltage boost circuit (10) according to a ninth aspect, which may be implemented in conjunction with the eighth aspect, the capacitance controller (7) includes first through (N−1)^{th} comparators. The first through (N−1)^{th} comparators compare the reference voltage (V0) with first through (N−1)^{th} threshold voltages, respectively. An (L+1)^{th} threshold voltage is less than an L^{th} threshold voltage, where L is an arbitrary integer falling within a range from 1 through N−2. The capacitance controller (7) compares the reference voltage (V0) with the first through (N−1)^{th} threshold voltages to determine, when finding the reference voltage (V0) greater than the first threshold voltage as a result of comparisons, that a current period be a first divided period. The capacitance controller (7) also compares the reference voltage (V0) with the first through (N−1)^{th} threshold voltages to determine, when finding the reference voltage (V0) greater than an (X+1)^{th} threshold voltage and equal to or less than an X^{th} threshold voltage as the result of the comparisons, that the current period be an (X+1)^{th} divided period. The capacitance controller (7) further compares the reference voltage (V0) with the first through (N−1)^{th} threshold voltages to determine, when finding the reference voltage (V0) equal to or less than the (N−1)^{th} threshold voltage as the result of the comparisons, that the current period be the N^{th} divided period, where X is an arbitrary integer falling within a range from 1 through N−2.

This aspect may reduce the noise caused to the output voltage (V2) due to the voltage boosting operation by the voltage booster (2).

In a voltage boost circuit (10) according to a tenth aspect, which may be implemented in conjunction with any one of the first to ninth aspects, the reference signal (S0) is a sinusoidal wave signal in which the reference voltage (V0) varies in a sinusoidal wave.

This aspect enables generating an output voltage (V2) having a sinusoidal waveform.

In a voltage boost circuit (10) according to an eleventh aspect, which may be implemented in conjunction with any one of the first to tenth aspects, the voltage divider (3) includes a first port (31), a second port (32), and a third port (33). The first port (31) is connected to the output port (24) of the voltage booster (2). The output voltage (V2) is delivered through the output port (24). The second port (32) outputs the fractional voltage signal (S1) therethrough. The third port (33) is connected to a reference potential node. A route connecting the first port (31) to the third port (33) includes: a first path (341) connecting the first port (31) to the second port (32); and a second path (342) connecting the second port (32) to the third port (33). The fractional voltage signal (S1) is based on a resistance ratio that is a ratio between a resistance value of the first path (341) and a resistance value of the second path (342). The resistance ratio of the voltage divider (3) is variable.

This aspect enables regulating the gain (i.e., the ratio of the output voltage V2 to the input voltage V1) by adjusting the resistance ratio.

In a voltage boost circuit (10) according to a twelfth aspect, which may be implemented in conjunction with the eleventh aspect, the voltage divider (3) further includes a variable resistor provided on the second path (342).

This aspect enables regulating the gain by adjusting the resistance value of the variable resistor. In addition, one terminal of the variable resistor is connected to the reference potential node (circuit ground), and therefore, the potential at the one terminal is fixed at 0 V. Thus, this aspect makes it easier to design the circuit than in a situation where the variation resistor is provided on the first path to make the potentials at both terminals of the variable resistor variable.

A voltage boost circuit (10) according to a thirteenth aspect, which may be implemented in conjunction with any one of the first to twelfth aspects, further includes the reference signal source (6).

This aspect enables generating an output voltage (V2) with a desired waveform while contributing to downsizing.

A voltage boost circuit (10) according to a fourteenth aspect, which may be implemented in conjunction with any one of the first to thirteenth aspects, further includes a failure diagnosis circuit (8). The failure diagnosis circuit (8) determines, by comparing the fractional voltage signal (S1) with a predetermined diagnosis signal (S3), whether any failure has occurred in the voltage boost circuit (10).

This aspect enables determining whether any failure has occurred in the voltage boost circuit (10).

A sensor device (100) according to a fifteenth aspect includes the voltage boost circuit (10) according to any one of the first to fourteenth aspects and an inertial sensor (102), to which the output voltage (V2) is applied from the voltage booster (2) of the voltage boost circuit (10).

This aspect allows an output voltage (V2) with a desired waveform to be applied to the inertial sensor (102).

### REFERENCE SIGNS LIST

10 Voltage Boost Circuit
1 Input Node
2 Voltage Booster
201 Connection Node (First Connection Node)
202 Connection Node (Second Connection Node)
21 Input Port
221 First Switch
222 Second Switch
223 Third Switch
231 First Capacitive Element
232 Second Capacitive Element
24 Output Port
3 Voltage Divider
31 First Port
32 Second Port
33 Third Port
341 First Path
342 Second Path
4 Comparator Unit
5 Voltage Boost Controller
6 Reference Signal Source
7 Capacitance Controller
70 Comparator
8 Failure Diagnosis Circuit
S0 Reference Signal
S1 Fractional Voltage Signal
S2 Comparison Signal
S3 Diagnosis Signal
T0 Cycle
V0 Reference Voltage
V1 Input Voltage
V2 Output Voltage
V3 Fractional Voltage
Vth Threshold Voltage
100 Sensor Device
102 Inertial Sensor

1. A voltage boost circuit comprising:
an input node configured to receive, from a reference signal source, a reference signal defined by a reference voltage;
a voltage booster configured to boost an input voltage to deliver an output voltage;
a voltage divider configured to divide the output voltage into a fractional voltage to generate a fractional voltage signal defined by the fractional voltage;
a comparator unit configured to compare the reference signal and the fractional voltage signal with each other to generate a comparison signal; and
a voltage boost controller configured to control, in accordance with the comparison signal, operation of the voltage booster to narrow a difference between the reference voltage and the fractional voltage.

2. The voltage boost circuit of claim 1, wherein
the voltage booster includes:
an input port configured to receive the input voltage;
an output port configured to deliver the output voltage;
a first switch, a second switch, and a third switch, which are connected in series in this order between the input port and the output port such that the first switch is located closer to the input port than the second switch or the third switch;
a first capacitive element having a first terminal and a second terminal, the first terminal of the first capacitive element being connected to a connection node between the first switch and the second switch, the second terminal of the first capacitive element being connected to the voltage boost controller; and
a second capacitive element having a first terminal and a second terminal, the first terminal of the second capacitive element being connected to a connection node between the second switch and the third switch, the second terminal of the second capacitive element being connected to the voltage boost controller, and
the voltage boost controller is configured to control, in accordance with the comparison signal, ON/OFF states of the first switch, the second switch, and the third switch, a potential at the second terminal of the first capacitive element, and a potential at the second terminal of the second capacitive element.

3. The voltage boost circuit of claim 2, wherein
at least one of the first capacitive element or the second capacitive element is a variable capacitance capacitive element.

4. The voltage boost circuit of claim 3, wherein
each of the first capacitive element and the second capacitive element is a variable capacitance capacitive element.

5. The voltage boost circuit of claim 3, further comprising a capacitance controller configured to control capacitance of the variable capacitance capacitive element, wherein
the capacitance controller is configured to control the capacitance in response to the reference signal.

6. The voltage boost circuit of claim 5, wherein
the reference signal is a signal having a waveform in which the reference voltage varies periodically in a predetermined cycle,
the predetermined cycle includes:
a first divided period; and
a second divided period in which the reference voltage is smaller than in the first divided period, and
the capacitance controller is configured to control the capacitance to make the capacitance smaller in the second divided period than in the first divided period.

7. The voltage boost circuit of claim 6, wherein
the capacitance controller includes a comparator configured to compare the reference voltage with a predetermined threshold voltage, and
the capacitance controller is configured to compare the reference voltage with the predetermined threshold voltage to:
determine, when finding the reference voltage greater than the predetermined threshold voltage as a result of comparison, that a current period be the first divided period; and
determine, when finding the reference voltage equal to or less than the predetermined threshold voltage as the result of the comparison, that the current period be the second divided period.

8. The voltage boost circuit of claim 5, wherein
the reference signal is a signal having a waveform in which the reference voltage varies periodically in a predetermined cycle,
the predetermined cycle includes first through N^{th} divided periods, where N is an integer equal to or greater than 2,
the reference voltage in an (M+1)^{th} divided period is less than the reference voltage in an M^{th} divided period, where M is an arbitrary integer falling within a range from 1 through N−1, and
the capacitance controller is configured to control the capacitance to make the capacitance smaller in the (M+1)^{th} divided period than in the M^{th} divided period.

9. The voltage boost circuit of claim 8, wherein
the capacitance controller includes first through (N−1)^{th} comparators configured to compare the reference voltage with first through (N−1)^{th} threshold voltages, respectively, where an (L+1)^{th} threshold voltage is less than an L^{th} threshold voltage and L is an arbitrary integer falling within a range from 1 through N−2,
the capacitance controller is configured to compare the reference voltage with the first through (N−1) th threshold voltages to:
determine, when finding the reference voltage greater than the first threshold voltage as a result of comparisons, that a current period be a first divided period;
determine, when finding the reference voltage greater than an (X+1)^{th} threshold voltage and equal to or less than an X^{th} threshold voltage as the result of the comparisons, that the current period be an (X+1)^{th} divided period, where X is an arbitrary integer falling within a range from 1 through N−2; and
determine, when finding the reference voltage equal to or less than the (N−1)^{th} threshold voltage as the result of the comparisons, that the current period be the N^{th} divided period.

10. The voltage boost circuit of claim 1, wherein
the reference signal is a sinusoidal wave signal in which the reference voltage varies in a sinusoidal wave.

11. The voltage boost circuit of claim 1, wherein
the voltage divider includes:
a first port connected to the output port of the voltage booster, the output voltage being delivered through the output port;
a second port configured to output the fractional voltage signal therethrough; and
a third port connected to a reference potential node,
a route connecting the first port to the third port includes:
a first path connecting the first port to the second port; and
a second path connecting the second port to the third port,
the fractional voltage signal is based on a resistance ratio that is a ratio between a resistance value of the first path and a resistance value of the second path, and
the resistance ratio of the voltage divider is variable.

12. The voltage boost circuit of claim 11, wherein
the voltage divider further includes a variable resistor provided on the second path.

13. The voltage boost circuit of claim 1, further comprising the reference signal source.

14. The voltage boost circuit of claim 1, further comprising a failure diagnosis circuit configured to determine, by comparing the fractional voltage signal with a predetermined diagnosis signal, whether any failure has occurred in the voltage boost circuit.

15. A sensor device comprising:
the voltage boost circuit of claim 1; and
an inertial sensor to which the output voltage is applied from the voltage booster of the voltage boost circuit.
